(19) United States
(12) Patent Application Publication
(10) Pub. No.: US 2012/0242349 A1
(43) Pub. Date: Sep. 27, 2012

(54) CAPACITANCE DETECTING DEVICE

(75) Inventor: Tomomi SHIMIZU, Aichi (JP)

(73) Assignee: KABUSHIKI KAISHA TOKAI RIKA DENKI SEISAKUSHO, Aichi (JP)

(21) Appl. No.: 13/358,773

(22) Filed: Jan. 26, 2012

(30) Foreign Application Priority Data
Mar. 22, 2011 (JP) 2011-062044

(51) Int. Cl. G01R 29/26

(52) U.S. Cl. 324/613

(57) ABSTRACT

A capacitance detecting device includes a detecting electrode to form a capacitance, an electrical current supply part to supply electrical current to the detecting electrode, and a control part to set different conditions of the electrical current supplied from the electrical current supply part to the detecting electrode, and judge a presence or absence of an electromagnetic noise at the detecting electrode based on an output value of the detecting electrode under the different conditions.

The present application is based on Japanese patent application No. 2011-062044 filed on Mar. 22, 2011, the entire contents of which are incorporated herein by reference.

### BACKGROUND OF THE INVENTION

1. Field of the Invention

This invention relates to a capacitance detecting device and, in particular, relates to capacitance detecting device having a function of detecting the presence or absence of a noise.

2. Description of the Related Art

A capacitance detecting device is known that can prevent a false detection caused by an influence of electromagnetic noise. The capacitance detecting device includes a detecting electrode configured to detect a capacitance and a noise detecting electrode configured to detect an influence of the electromagnetic noise based on the capacitance, and has a configuration that detection by the detecting electrode is forbidden when a capacitance (a first count value) detected by the detecting electrode exceeds a predetermined first upper limit and a capacitance (a second count value) detected by the noise detecting electrode exceeds a predetermined second upper limit (for example, refer to JP-A-2008-80952).

As disclosed in JP-A-2008-80952, the noise detecting electrode for detecting the electromagnetic noise is equipped in addition to the detecting electrode for detecting the capacitance, such that the capacitance detecting device can be insusceptible to the electromagnetic noise.

### SUMMARY OF THE INVENTION

However, the capacitance detecting device of JP-A-2008-80952 has a problem that it is highly constrained in design since it needs to have the additional noise detecting electrode other than the detecting electrode, and to provide the noise detecting electrode with the same characteristic such as easiness to receive a noise as the detecting electrode, e.g., by placing it adjacent to the detecting electrode.

Accordingly, it is an object of the invention to provide a capacitance detecting device that is capable of accurately detecting the presence or absence of a noise without the additional noise detecting electrode.

(1) According to one embodiment of the invention, a capacitance detecting device comprises:

a detecting electrode to form a capacitance;

an electrical current supply part to supply electrical current to the detecting electrode; and

a control part to set different conditions of the electrical current supplied from the electrical current supply part to the detecting electrode, and judge a presence or absence of an electromagnetic noise at the detecting electrode based on an output value of the detecting electrode under the different conditions.

In the above embodiment (1) of the invention, the following modifications and changes can be made.

(i) The control part comprises a comparison portion to compare the output values of the detecting electrode under the different conditions, and changes a threshold value in the comparison of the comparison portion.

(ii) The control part measures a time until the output value reaches the threshold value, and compares the measured time in the comparison portion so as to judge the presence or absence of the electromagnetic noise.

(iii) The control part determines the absence of the electromagnetic noise when the measured time is changed in proportion to amount of the change in the threshold value.

(iv) The control part determines the presence of the electromagnetic noise when the measured time is not changed in proportion to amount of the change in the threshold value.

(v) The threshold value comprises not less than three threshold values.

(vi) The capacitance detecting device is used as a capacitance type touch sensor or switch module.

Points of the Invention

According to one embodiment of the invention, a capacitance detecting device is constructed such that a threshold value (electrode voltage) is set to be different values such as values (Vₜₕ), (Vₜₕ/2) in case of comparing the electrode voltage (V_{EL}) of a detecting electrode in a comparator, and the presence or absence of a noise is judged based on plural comparison results. Thus, noise detection at the detecting electrode can be performed without any additional hardware such as an electrode for detecting only a noise.

### BRIEF DESCRIPTION OF THE DRAWINGS

The preferred embodiments according to the invention will be explained below referring to the drawings, wherein:

FIG. 1 is a circuit configuration diagram showing a capacitance detecting device according to an embodiment of the invention;

FIG. 2A is a graph showing a relationship between a time (t) of detecting electrode and an electrode voltage (V_{EL}), and showing a time (T_{C}) until reaching a threshold value (Vₜₕ) in a comparator;

FIG. 2B is a graph showing a relationship between a time (t) of detecting electrode and an electrode voltage (V_{EL}), and showing a time (T_{C}/2) until reaching a threshold value (Vₜₕ/2) in a comparator;

FIG. 3A is a graph showing a signal waveform in case that an electromagnetic noise is applied to the detecting electrode in FIGS. 2A and 2B, and showing a time until reaching a threshold value (Vₜₕ) in a comparator;

FIG. 3B is a graph showing a signal waveform in case that an electromagnetic noise is applied to the detecting electrode in FIGS. 2A and 2B, and showing a time until reaching a threshold value (Vₜₕ/2) in a comparator;

FIG. 4A is a waveform diagram showing a waveform of an electrode voltage (V_{EL}) of the detecting electrode in case that the presence or absence of an electromagnetic noise is judged;

FIG. 4B is a waveform diagram showing a waveform of a reference signal (clock) (V₁) for the right time to carry out a discharge of the detecting electrode;

FIG. 4C is a waveform diagram showing a waveform of a reference signal (clock) (V₂) for the start of measurement;

FIG. 4D is a waveform diagram showing a waveform of an output (V_{C}) of comparator;

FIG. 5 is a flowchart showing an example of a judgment flow of a control part of a capacitance detecting device according to an embodiment of the invention;

FIG. 6A is a waveform diagram showing a waveform of an electrode voltage (V_{EL}) of the detecting electrode in case that the presence or absence of an electromagnetic noise is judged when a touch operation is applied to the detecting electrode;

FIG. 6B is a waveform diagram showing a waveform of a reference signal (clock) (V₁) for the right time to carry out a discharge of the detecting electrode;

FIG. 6C is a waveform diagram showing a waveform of a reference signal (clock) (V₂) for the start of measurement; and

FIG. 6D is a waveform diagram showing a waveform of an output (V_{C}) of comparator.

### DETAILED DESCRIPTION OF THE PREFERRED EMBODIMENTS

Configuration of Capacitance Detecting Device 10

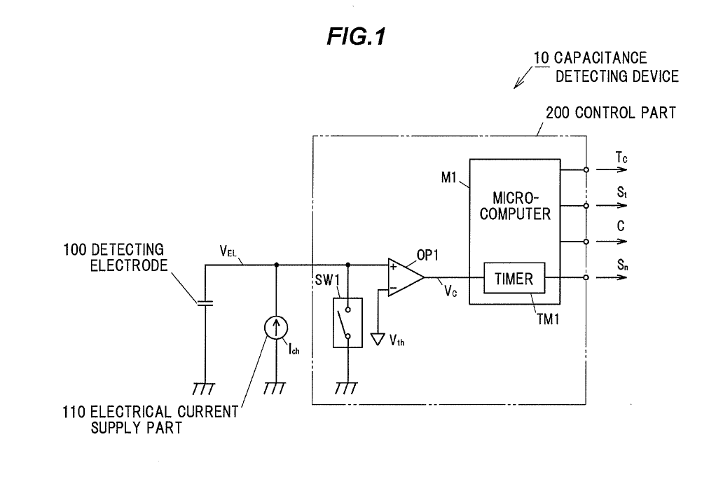

FIG. 1 is a circuit configuration diagram showing a capacitance detecting device according to an embodiment of the invention. The capacitance detecting device 10 includes a detecting electrode 100 configured to form a capacitance, an electrical current supply part 110 configured to supply electrical current to the detecting electrode 100 and a control part 200 configured to control to change a condition of the electrical current supplied from the electrical current supply part 110 to the detecting electrode 100 to different conditions from each other, and judge the presence or absence of an electromagnetic noise on the detecting electrode 100 based on an output value of the detecting electrode 100 in each of the different conditions. The capacitance detecting device 10 includes only the detecting electrode 100 configured to detect a capacitance without including a noise detecting electrode installed separately, and is capable of detecting both of a capacitance and the presence or absence of a noise in the detecting electrode 100.

Here, the presence or absence of an electromagnetic noise means a state that an electromagnetic noise is applied or not applied to the detecting electrode 100 by an influence of circumference environment. In addition, the state of presence of an electromagnetic noise means a state that the measurement accuracy of the capacitance value is lowered so as to cause an adverse effect such as a false operation in the measurement of capacitance detection of the detecting electrode 100.

The detecting electrode 100 has a configuration that conductive members having a plate-like shape are arranged so as to face each other, and one electrode is connected to a ground level and another electrode is connected to an input terminal of a comparator OP1, a switch element SW1 configured to carry out a switching control of discharge and charge and the electrical current supply part 110 configured to charge. Here, in case that a constant electrical current (I_{CH}) is supplied to the detecting electrode 100 in which electrical charge is zero so as to charge the detecting electrode 100, and a time (T_{C}) until reaching a setting voltage (threshold value) (Vₜₕ) is measured, the capacitance (C) of the detecting electrode 100 is calculated by a formula of (C)=(I_{CH})×(T_{C}) (Vₜₕ).

As shown in FIG. 1, the control part 200 is configured to include the electrical current supply part 110 configured to supply the constant electrical current (I_{CH}) to the detecting electrode 100, the switch element SW1 configured to discharge electrical charge accumulated in the detecting electrode 100, the comparator OP1 configured to output by comparing the electrode voltage (V_{EL}) of the detecting electrode 100 with the setting voltage (Vₜₕ), a timer (timer counter) TM1 configured to measure a time of a low (Lo) level of an output of the comparator OP1 and a microcomputer M1 configured to control the switch element SW1 and carry out various calculations from the output of the timer TM1 so as to judge whether an electromagnetic noise is applied to the detecting electrode 100 or not.

The timer (timer counter) TM1 is configured to measure a time between a time when the charge to the detecting electrode 100 is started and a time when the electrode voltage (V_{EL}) of the detecting electrode 100 reaches a setting voltage (threshold value) of the comparator OP1. In the embodiment, a timer housed in the microcomputer M1 is used, but a timer installed externally can be also used.

The comparator OP1 compares the electrode voltage (V_{EL}) of the detecting electrode 100 and the setting voltage (threshold value) so as to output the output (V_{C}) of the comparator that is inverted, and is connected to an input part of the timer TM1. The setting voltage (threshold value) of the comparator OP1 is appropriately changed to the threshold value (Vₜₕ), the threshold value (Vₜₕ/2) or the like by the microcomputer M1 so as to be set.

Further, a switching part (not shown) that is to be connected to the detecting electrode 100 only at the time of the charge to the detecting electrode 100 is installed in the electrical current supply part 110. In addition, as the electrical current supply part 110, an electrical current source that is capable of supplying a predetermined charge to the detecting electrode 100 during a predetermined period can be also used other than the constant electrical current source.

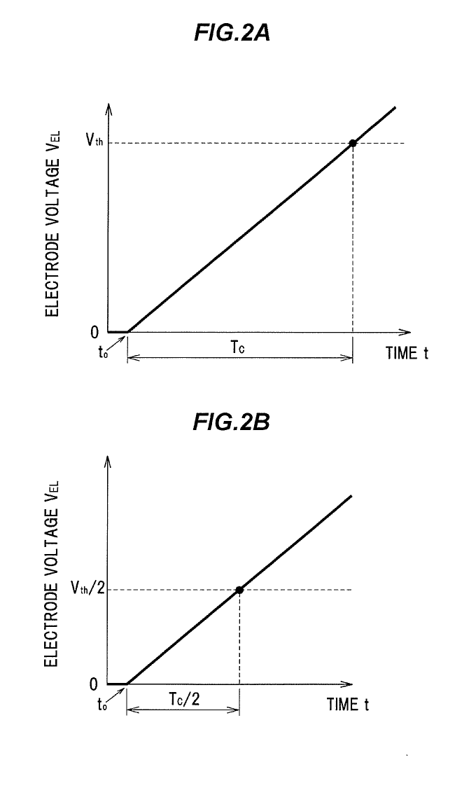

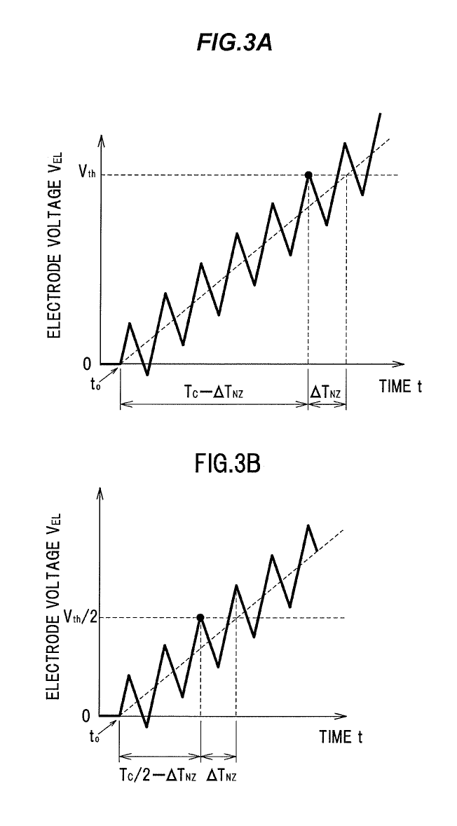

FIG. 2A is a graph showing a relationship between a time (t) of detecting electrode and an electrode voltage (V_{EL}), and showing a time (T_{C}) until reaching a threshold value (Vₜₕ) in a comparator, and FIG. 2B is a graph showing a relationship between a time (t) of detecting electrode and an electrode voltage (V_{EL}), and showing a time (T_{C}/2) until reaching a threshold value (Vₜₕ/2) in a comparator. In addition, FIG. 3A is a graph showing a signal waveform in case that an electromagnetic noise is applied to the detecting electrode in FIGS. 2A and 2B, and showing a time until reaching a threshold value (Vₜₕ) in a comparator, and FIG. 3B is a graph showing a signal waveform in case that an electromagnetic noise is applied to the detecting electrode in FIGS. 2A and 2B, and showing a time until reaching a threshold value (Vₜₕ/2) in a comparator.

In FIG. 2A, after the detecting electrode 100 is discharged, the charge is started at a time (t₀), and the electrode voltage (V_{EL}) of the detecting electrode 100 reaches the setting voltage (Vₜₕ) at a time (T_{C}). In addition, the charge to the detecting electrode 100 is carried out by supplying a constant electrical current (I_{CH}), thus as shown in FIG. 2B, when the setting voltage (Vₜₕ) is set to a voltage (Vₜₕ/2), the electrode voltage (V_{EL}) reaches the setting voltage (Vₜₕ/2) at a time of (T_{C}/2).

On the other hand, in a state that an electromagnetic noise is applied to the detecting electrode 100, as shown in FIGS. 3A, 3B, the waveform has a shape that an electromagnetic noise is applied to the charging curve. In FIG. 3A, a time until reaching a threshold value (Vₜₕ) in the comparator OP1 becomes less by a time (ΔT_{NZ}) than that of a state that the noise is absent since the peak of the noise increases the electrode voltage (V_{EL}) temporarily. Namely, in a state that the noise is present, a time that elapses before the output of the comparator OP1 is inverted becomes a time (T_{C}/2-ΔT_{NZ}). In addition, as shown in FIG. 3B, in case that the setting voltage is set to a voltage (Vₜₕ/2), since the increase of the electrode voltage (V_{EL}) is almost the same as that of the case shown in FIG. 3A, the time until reaching a threshold value (Vₜₕ) in the comparator OP1 becomes less by a time (ΔT_{NZ}) similarly to FIG. 3A than that of a state that the noise is absent. Namely, in a state that the noise is present, a time that elapses before the output of the comparator OP1 is inverted becomes a time (T_{C}/2-ΔT_{NZ}).

In a state that the noise is absent, from FIGS. 2A, 2B, the value of capacitance (C) of the detecting electrode 100 is calculated from the following formulae.

Namely, in case that the threshold value of the comparator OP1 is a voltage (Vₜₕ), from FIG. 2A, the value of capacitance (C) is shown by the following formula.

(C)=(I_{CH})×(T_{C})/(Vₜₕ)

In addition, in case that the threshold value of the comparator OP1 is a voltage (Vₜₕ/2), from FIG. 2B, the value of capacitance (C) is shown by the following formula.

(C)=(I_{CH})×(T_{C/}2)/(Vₜₕ/2).

Accordingly, in a state that the noise is absent, in any calculation result, the calculated values of capacitance (C) correspond with each other.

On the other hand, in a state that the noise is present, from FIGS. 3A, 3B, the value of capacitance (C) of the detecting electrode 100 is calculated from the following formulae.

Namely, in case that the threshold value of the comparator OP1 is a voltage (Vₜₕ), from FIG. 3A, the value of capacitance (C) is shown by the following formula.

(C)=(I_{CH})×(T_{C}−ΔT_{NZ})/(Vₜₕ)

In addition, in case that the threshold value of the comparator OP1 is a voltage (Vₜₕ/2), from FIG. 3B, the value of capacitance (C′) is shown by the following formula.

(C′)=(I_{CH})×(T_{C}/2−ΔT_{NZ})/(Vₜₕ/2).

Accordingly, in a state that the noise is present, the results calculated by the two formulae do not correspond with each other. This is due to the fact that the charge to the detecting electrode 100 by the constant electrical current source is varied by changing the setting of the threshold value, but the noise component is not varied.

Judging Presence or Absence of Noise

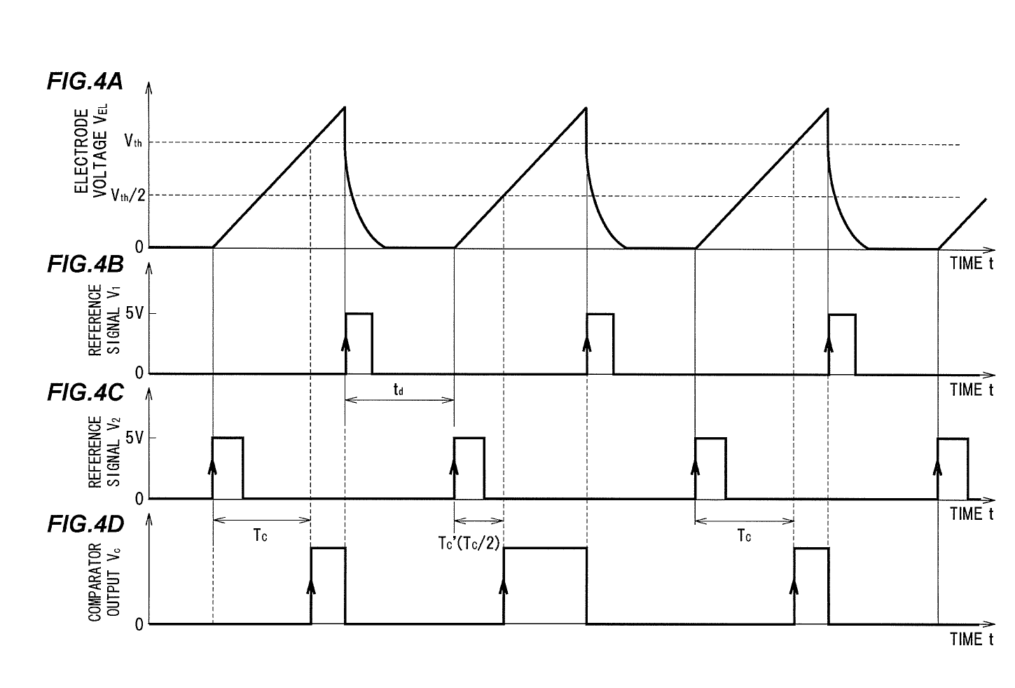

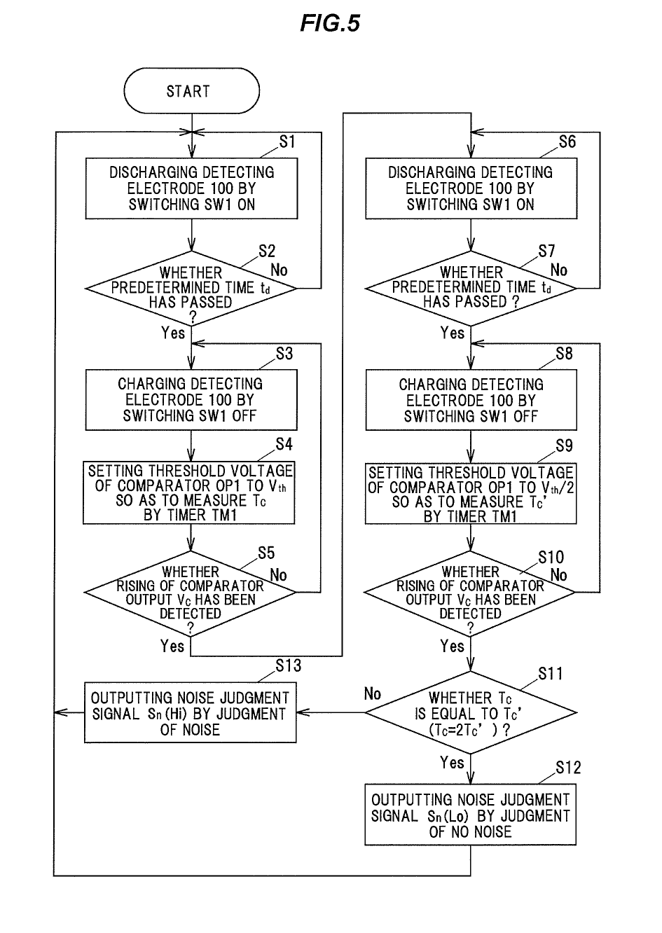

FIG. 4A is a waveform diagram showing a waveform of an electrode voltage (V_{EL}) of the detecting electrode in case that the presence or absence of an electromagnetic noise is judged, FIG. 4B is a waveform diagram showing a waveform of a reference signal (clock) (V₁) for the right time to carry out a discharge of the detecting electrode, FIG. 4C is a waveform diagram showing a waveform of a reference signal (clock) (V₂) for the start of measurement, and FIG. 4D is a waveform diagram showing a waveform of an output (V_{C}) of comparator. In addition, FIG. 5 is a flowchart showing an example of a judgment flow of a control part of a capacitance detecting device according to an embodiment of the invention. Hereinafter, the embodiment will be explained in accordance with the steps shown in the flowchart in reference to FIGS. 4A to 4D.

When the noise judgment flow of the capacitance detecting device 10 is started, first, the microcomputer M1 switches the switching SW1 on, and discharges electrical charge accumulated in the detecting electrode 100 (Step 1 shown in FIG. 5 as S1). Namely, the discharge is started by using the rising of the reference signal (clock) (V₁) shown in FIG. 4B as a trigger. At this time, the charge supply from the electrical current supply part 110 that is a constant electrical current source is turned off.

The microcomputer M1 judges whether a predetermined time (t_{d}) has passed from the turning on of the switch element SW1. The predetermined time (t_{d}) is the reference signal (clock) (V₂) shown in FIG. 4C of which phase is delayed by the predetermined time (t_{d}) from that of the reference signal (clock) (V₁). The predetermined time (t_{d}) is a time that is set based on a time constant at the time of the discharge and charge of the detecting electrode 100, and if the time (t_{d}) has passed, electrical charge of the detecting electrode 100 becomes almost zero. If the microcomputer M1 judges that the predetermined time (t_{d}) has passed, the procedure proceeds to the next step, on the other hand if the microcomputer M1 judges that the predetermined time (t_{d}) does not have passed, the procedure returns to Step 1 so as to continue the discharge (Step 2 shown in FIG. 5 as S2).

The microcomputer M1 turns the switch element SW1 off, and starts to charge the constant electrical current (I_{CH}) from the electrical current supply part 110 to the detecting electrode 100 by using the rising of the reference signal (V₂) as a trigger (Step 3 shown in FIG. 5 as S3).

The microcomputer M1 sets the threshold value voltage of the comparator OP1 to a voltage (Vₜₕ) so as to measure a time (T_{c}) by the timer TM1 (Step 4 shown in FIG. 5 as S4). The time (T_{c}) is a time from the rising of the reference signal (clock) (V₂) until the output (V_{C}) of the comparator OP1 shown in FIG. 4D becomes a high level, namely a time from the start of the charge to the detecting electrode 100 until the electrode voltage (V_{EL}) shown in FIG. 4A reaches the threshold value (Vₜₕ).

The microcomputer M1 judges whether the rising (inversion) of the output (V_{C}) of the comparator OP1 has been detected. If it has been detected, the procedure proceeds to the next step, on the other hand if it does not have been detected, the procedure returns to Step 3 so as to continue the measurement by the timer (Step 5 shown in FIG. 5 as S5).

The microcomputer M1 turns the switch element SW1 on, and discharges electrical charge accumulated in the detecting electrode 100 (Step 6 shown in FIG. 5 as S6). Operation in Step 6 is the same as that in Step 1. Namely, the discharge is started by using the rising of the reference signal (clock) (V₁) shown in FIG. 4B as a trigger. At this time, the charge supply from the electrical current supply part 110 that is a constant electrical current source is turned off.

The microcomputer M1 judges whether a predetermined time (t_{d}) has passed from the turning on of the switch element SW1 (Step 7 shown in FIG. 5 as S7). Operation in Step 7 is the same as that in Step 2. Namely, the predetermined time (t_{d}) is the reference signal (clock) (V₂) shown in FIG. 4C of which phase is delayed by the predetermined time (t_{d}) from that of the reference signal (clock) (V₁). The predetermined time (t_{d}) is a time that is set based on a time constant at the time of the discharge and charge of the detecting electrode 100, and if the time (t_{d}) has passed, electrical charge of the detecting electrode 100 becomes almost zero. If the microcomputer M1 judges that the predetermined time (t_{d}) has passed, the procedure proceeds to the next step, on the other hand if the microcomputer M1 judges that the predetermined time (t_{d}) does not have passed, the procedure returns to Step 6 so as to continue the discharge.

The microcomputer M1 turns the switch element SW1 off, and starts to charge the constant electrical current (I_{CH}) from the electrical current supply part 110 to the detecting electrode 100 by using the rising of the reference signal (V₂) as a trigger (Step 8 shown in FIG. 5 as S8). Operation in Step 8 is the same as that in Step 3.

The microcomputer M1 sets the threshold value voltage of the comparator OP1 to a voltage (Vₜₕ/2) so as to measure a time (T_{c}′) by the timer TM1 (Step 9 shown in FIG. 5 as S9). The time (T_{c}′) is a time from the rising of the reference signal (clock) (V₂) until the output (V_{C}) of the comparator OP1 shown in FIG. 4D becomes a high level, namely a time from the start of the charge to the detecting electrode 100 until the electrode voltage (V_{EL}) shown in FIG. 4A reaches the threshold value (Vₜₕ/2). Operation in Step 9 is different from that in Step 4 in the setting value of the threshold value.

The microcomputer M1 judges whether the rising (inversion) of the output (V_{C}) of the comparator OP1 has been detected. If it has been detected, the procedure proceeds to the next step, on the other hand if it does not have been detected, the procedure returns to Step 8 so as to continue the measurement by the timer (Step 10 shown in FIG. 5 as S10). Operation in Step 10 is the same as that in Step 5.

The microcomputer M1 judges whether the time (T_{c}) measured in Step 4 is equal to the time (T_{c}′) measured in Step 9, namely whether a formula of T_{c}=T_{c}′ is satisfied (Step 11 shown in FIG. 5 as S11). As described above, if the noise is absent on the detecting electrode 100, the time (T_{c}) becomes equal to the time (2T_{c}′), namely a formula of T_{c}=2T_{c}′ is satisfied, on the other hand, if the noise is present on the detecting electrode 100, the time (T_{c}) does not become equal to the time (2T_{c}′), namely a formula of T_{c}≠2T_{c}′ is satisfied.

In case of T_{c}=2T_{c}′, by a judgment of no noise, for example, a noise judgment signal Sₙ is output from the microcomputer M1 as Lo (noise is absent) and the procedure returns to Step 1 (Step 12 shown in FIG. 5 as S12).

In case of T_{c}≠2T_{c}′, by a judgment of noise, for example, a noise judgment signal Sₙ is output from the microcomputer M1 as Hi (noise is present) and the procedure returns to Step 1 (Step 13 shown in FIG. 5 as S13).

The above-mentioned series of steps are carried out repeatedly, and the judgment of the presence or absence of the noise is always carried out until an interrupt discontinuation signal is input.

Detection of Touch Operation to the Detecting Electrode 100

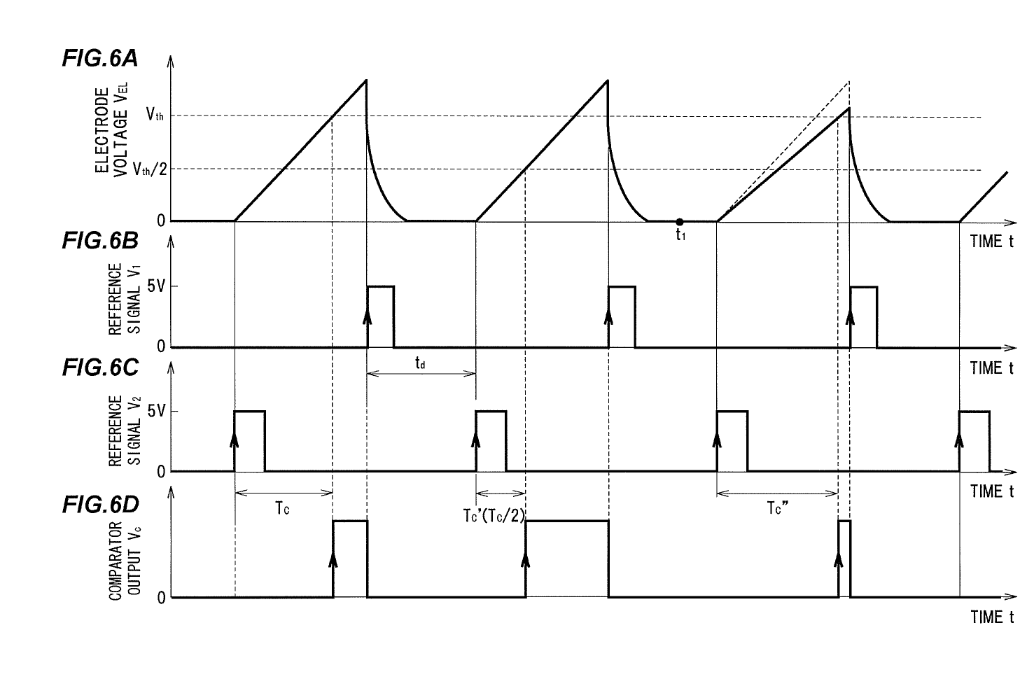

FIG. 6A is a waveform diagram showing a waveform of an electrode voltage (V_{EL}) of the detecting electrode in case that the presence or absence of an electromagnetic noise is judged when a touch operation is applied to the detecting electrode, FIG. 6B is a waveform diagram showing a waveform of a reference signal (clock) (V₁) for the right time to carry out a discharge of the detecting electrode, FIG. 6C is a waveform diagram showing a waveform of a reference signal (clock) (V₂) for the start of measurement, and FIG. 6D is a waveform diagram showing a waveform of an output (V_{C}) of comparator.

For example, in FIG. 6A, a case that a touch operation has been carried out to the detecting electrode 100 at the time (t₁) is simulated. At this time, the capacitance of the detecting electrode 100 is varied by the touch of operator, and usually the capacitance is increased. Due to this, as shown in FIG. 6A, the charge time to the detecting electrode 100 is lengthened so as to vary the original time (T_{c}) to a time (T_{c}″). The microcomputer M1 detects the variation of the charge time, thereby the presence or absence of the touch operation to the detecting electrode 100 can be judged so that a touch detection signal (Sₜ) can be generated.

In case that as mentioned above, the presence or absence of the touch operation to the detecting electrode 100 is judged, the judgment of the presence or absence of the noise shown in the above-mentioned Step 1 to Step 13 is always carried out, thus the high accuracy judgment of the presence or absence of the touch operation can be carried out by that the judgment of the presence of the touch operation in case of the judgment of the presence of the noise is invalidated.

As shown in FIG. 1, the microcomputer M1 can output the capacitances (C), (C′) calculated, the times (T_{C}), (T_{C}′) until the electrode voltage (V_{EL}) reaches threshold values (Vₜₕ), (Vₜₕ/2), the noise judgment signal (Sₙ), and the touch detection signal (Sₜ) as explained above to the outside so that they can be utilized for various calculation, control and the like.

### EFFECTS OF THE EMBODIMENT

In accordance with the capacitance detecting device 10 according to the embodiment of the invention, the following advantages can be provided.

(1) The capacitance detecting device 10 has a configuration that the setting threshold value is set to different values such as values (Vₜₕ), (Vₜₕ/2) in case of comparing with the electrode voltage (V_{EL}) of the detecting electrode 100 in the comparator OP1, and the judgment of the presence or absence of the noise is carried out based on a plurality of the comparison results. Consequently, the noise detection can be carried out without adding a new hardware such as an electrode for noise detection only for the noise detection.
(2) Since the noise detection is carried out by the detecting electrode 100, the problem can be eliminated, that conditions such as ease of reception of a noise are varied by that the installation places are different from each other, for example, the problem caused by that an electrode for noise detection is installed separately can be eliminated. Due to this, it is not needed to adjust the conditions such as ease of reception of a noise, thereby the detection of the presence or absence of the noise can be easily carried out with a high degree of accuracy.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth. For example, the presence or absence of the noise can be also judged by means such as comparison of the values of integral of the electrode voltage (V_{EL}) at a predetermined time, instead of comparison judgment of the times (T_{C}), (T_{C}′) measured by a timer based on the output of the comparator OP1. In addition, in the embodiment, the comparison in the comparator OP1 is carried out by varying the threshold value to the two kind of values (Vₜₕ), (Vₜₕ/2), but not limited to this, a plurality of comparisons based on not less than tree threshold values can be also carried out, thereby the detection of the presence or absence of the noise can be carried out with a higher degree of accuracy.

What is claimed is:

1. A capacitance detecting device, comprising:
a detecting electrode to form a capacitance;
an electrical current supply part to supply electrical current to the detecting electrode; and
a control part to set different conditions of the electrical current supplied from the electrical current supply part to the detecting electrode, and judge a presence or absence of an electromagnetic noise at the detecting electrode based on an output value of the detecting electrode under the different conditions.

2. The capacitance detecting device according to claim 1, wherein the control part comprises a comparison portion to compare the output values of the detecting electrode under the different conditions, and changes a threshold value in the comparison of the comparison portion.

3. The capacitance detecting device according to claim 2, wherein the control part measures a time until the output value reaches the threshold value, and compares the measured time in the comparison portion so as to judge the presence or absence of the electromagnetic noise.

4. The capacitance detecting device according to claim 3, wherein the control part determines the absence of the electromagnetic noise when the measured time is changed in proportion to amount of the change in the threshold value.

5. The capacitance detecting device according to claim 3, wherein the control part determines the presence of the electromagnetic noise when the measured time is not changed in proportion to amount of the change in the threshold value.

6. The capacitance detecting device according to claim 2, wherein the threshold value comprises not less than three threshold values.

7. The capacitance detecting device according to claim 1, wherein the capacitance detecting device is used as a capacitance type touch sensor or switch module.
